(19) United States
(12) Patent Application Publication
(10) Pub. No.: US 2012/0280843 A1
(43) Pub. Date: Nov. 8, 2012

(54) BROADBAND DELTA-SIGMA ADC MODULATOR LOOP WITH DELAY COMPENSATION

(75) Inventors: Yi-Lin TSAI, Taipei (TW); Tsung-Hsien LIN, Taipei (TW)

(73) Assignee: National Taiwan University, Taipei (TW)

(21) Appl. No.: 13/226,545

(22) Filed: Sep. 7, 2011

(30) Foreign Application Priority Data
May 5, 2011 (TW) 100115743

(51) Int. Cl. H03M 3/02; H03M 1/12

(52) U.S. Cl. 341/110

(57) ABSTRACT

An exemplary delta-sigma modulator loop applied to convert a continuous-time input signal into a discrete-time output signal. The delta-sigma modulator loop includes a conversion unit, a sampling unit, a quantization unit, a compensation unit, and a digital-to-analog converter unit. The conversion unit converts an error signal relevant to the input signal through a transfer function to generate a converted signal. The sampling unit samples the converted signal to generate a sampling signal. The quantization unit quantizes the sampling signal to obtain the output signal. The compensation unit receives the output signal and compensates a time delay of the received output signal to generate a compensation signal. The digital-to-analog converter unit is electrically coupled to the compensation unit and the conversion unit to convert the compensation signal to generate a feedback signal for regulating the error signal.

### TECHNICAL FIELD

The disclosure generally relates to a delta-sigma analog-to-digital converter (ADC) modulator loop and, particularly to a broadband delta-sigma ADC modulator loop with delay compensation function.

### BACKGROUND

Delta-sigma ADC modulators can be classified into two categories, one category is called as continuous-time type, and the other category is called as discrete-time type. The continuous-time type delta-sigma ADC modulator has the characteristic of low power consumption and is suitable for broadband applications.

A delta-sigma ADC modulator loop is a solution of using oversampling frequency and noise shaping techniques to improve a signal to noise ratio (SNR) of ADC. Compared with other designs of ADC, because the delta-sigma ADC modulator loop has the merits of very high resolution under limited bandwidth, quick response of error reduction, and the circuit thereof being easy to realize, etc., the delta-sigma ADC modulator loop is very fit for applying to a high-speed continuous-time type ADC.

FIG. 1A, is a schematic functional block diagram of a conventional delta-sigma ADC modulator loop. In the high-speed continuous-time type delta-sigma ADC modulator loop, a continuous-time input signal x(t) is converted into a discrete-time output signal y[n] as output. In particular, the delta-sigma ADC modulator loop roughly estimates the magnitude of the input signal x(t), measures an error of the input signal, performs an integration operation to the error and finally compensates the error. In the course of the integration value of the error is finite, the average value of output signal y[n] is approximately equal to the average value of input signal x(t).

As depicted in FIG. 1A, the conventional delta-sigma ADC modulator loop includes a conversion unit 101, a sampling unit 102, a quantization unit 103 and a digital-to-analog converter (DAC) unit 104. In addition, because there is a delayed time difference τ between the clock signal used by the DAC unit 104 and the sampling clock signal of the sampling unit 102, and the influence of the time difference τ to the system is represented by a loop delay (e^{-sτ}) 106.

FIG. 1B is a schematic timing diagram showing a time difference τ between the analog-to-digital conversion clock signal clk_{ADC} used by the sampling unit and the digital-to-analog conversion clock signal clk_{DAC} used by the DAC unit 104 in the conventional delta-sigma ADC modulator loop. Herein, FIG. 1B represents that the signal generation time of the DAC unit 104 when the output signal is sent to the DAC unit 104 and the analog-to-digital conversion clock signal clk_{ADC} used by the sampling unit 102 have the time difference τ.

In short, the cause of loop delay in the delta-sigma ADC modulator loop is as follows: ideally, the ADC must change the output signal synchronously when the input signal occurs, however, in the applications of high frequency, the period of each analog-to-digital conversion clock signal clk_{ADC} is very short, contradistinctively, the switching speed of the sampling unit 102 could not catch up with the generation time point of input signal and therefore the output signal is affected consequently.

Under the influence of the extra loop delay, the noise transfer function (NTF) of the delta-sigma ADC modulator loop would be changed correspondingly. When the non-return-to-zero (NRZ) application is taken as an example, the extra loop delay will make the NTF be increased with one pole, i.e., the whole transfer function is increased with one order.

In other words, the existence of extra loop delay would result in coefficients of the actual transfer function in the system is inconsistent with that of the original designed transfer function, and such phenomenon is also called as coefficient mismatch. Besides the transfer function would be changed, the loop delay even causes the pole position moved outside a unit circle, resulting in the increase of frequency band noise and the degradation of loop stability.

When loop delay compared with each sampling period cannot be ignored, excess loop delay may generate, and thus the influence of the loop delay applied to the delta-sigma ADC modulator loop is more serious, Therefore, how to improve the loop delay of the delta-sigma ADC modulator loop is becoming an important topic for the high-speed continuous-time type ADC.

FIG. 2 is a schematic functional block diagram showing that an assistant DAC unit 2052 is used to add the signal outputted from the DAC unit 204 and the converted signal generated from the conversion unit 201 to thereby compensate the influence of the loop delay 206 in the prior art.

In regard to the ADC unit, the efficiency estimation thereof is generally indicated by a figure of merit (F.O.M.). A formula of the F.O.M. is that: F.O.M=P/(2*BW*2^{N}), where P represents power consumption, BW represents a transformable bandwidth, and N represents a bit number (i.e., resolution) provided by the quantization unit 203 signally connected with the sampling unit 202.

When the value of the F.O.M. is smaller, the efficiency of the ADC is better. Accordingly, on the condition of fixed bandwidth and resolution, a lower power consumption indicates a better efficiency.

It can be found by further studying the solution of FIG. 2 according to the definition of the F.O.M. that: although the solution of FIG. 2 improves the loop delay phenomenon, other drawbacks may be derived. That is, since the use of analog adder (or summing amplifier) 2051, the delta-sigma ADC modulator loop will generate a static power consumption, so that the estimated efficiency of the delta-sigma ADC modulator loop is degraded.

According to the above-mentioned description, it can be found that the above methods for compensating the time delay in the prior art still have some drawbacks needed to be further improved.

### SUMMARY OF EMBODIMENTS

In one aspect, a delta-sigma ADC modulator loop in accordance with an embodiment is applied to convert a continuous-time input signal into a discrete-time output signal. The delta-sigma ADC modulator loop includes a conversion unit, a sampling unit, a quantization unit, a compensation unit, and a digital-to-analog converter unit. The conversion unit converts an error signal relevant to the input signal through a transfer function to thereby generate a converted signal. The sampling unit samples the converted signal to thereby generate a sampling signal. The quantization unit quantizes the sampling signal to obtain the output signal. The compensation unit receives the output signal and compensates a time delay of the received output signal to thereby generate a compensation signal. The digital-to-analog converter unit is electrically coupled to the compensation unit and the conversion unit and converts the compensation signal to thereby generate a feedback signal for regulating the error signal.

In one embodiment, a compensation transfer function for the compensation unit is obtained according to the time delay and an approximation formula.

In one embodiment, the compensation unit includes a constant operand and a sampling time delay operand.

In one embodiment, the output signal is converted into a constant operation output signal and a delay operation output signal respectively according to the constant operand and the sampling time delay operand, and the compensation signal correspondingly is obtained according to the constant operation output signal and the delay operation output signal.

In one embodiment, the error signal is obtained according to the input signal cooperative with the feedback signal.

In another aspect, a delta-sigma ADC modulator loop in accordance with another embodiment is applied to convert a continuous-time input signal into a discrete-time output signal. The delta-sigma ADC modulator loop includes a conversion unit, a sampling unit, a quantization unit, a first digital-to-analog converter unit, and a compensation unit. The conversion unit converts the input signal through a transfer function to thereby generate a converted signal. The sampling unit is dynamically connected to the conversion unit to thereby generate a sampling signal according to the converted signal. The quantization unit is signally connected to the sampling unit to quantize the sampling signal to thereby obtain the output signal. The first digital-to-analog converter unit is signally connected to the output signal. The compensation unit is signally connected to the output signal and the input signal and provides a delay compensation to the output signal.

In one embodiment, a compensation transfer function for the compensation unit to provide the delay compensation is obtained according to a time delay of the output signal and an approximation formula.

In one embodiment, the compensation unit and the first digital-to-analog converter unit are arranged between the output signal and the input signal in parallel.

In one embodiment, the compensation unit includes a second digital-to-analog converter unit and a sampling time delay operand.

In one embodiment, a first current flowing through the first digital-to-analog converter unit is a multiple of a second current flowing through the second digital-to-analog converter unit.

Other objectives, features and advantages of the disclosure will be further understood from the further technological features disclosed by the embodiments of the present disclosure wherein there are shown and described preferred embodiments, simply by way of illustration of modes best suited to carry out the disclosure.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A is a schematic functional block diagram of a conventional delta-sigma ADC modulator loop;

FIG. 1B is a schematic timing diagram showing that an analog-to-digital conversion clock pulse used by the sampling unit and a digital-to-analog conversion clock pulse used by the digital-to-analog converter unit in the conventional delta-sigma ADC modulator loop have a time difference;

FIG. 2 is a schematic functional block diagram showing that an assistant digital-to-analog converter unit is used to add the signal outputted from the digital-to-analog converter unit and the converted signal generated by the conversion unit to thereby compensate the influence of the loop delay in the prior art;

FIG. 3A is a schematic functional block diagram of a delta-sigma ADC modulator loop in accordance with a first exemplary embodiment for compensating a loop delay;

FIG. 3B is a schematic functional block diagram of the delta-sigma ADC modulator loop in accordance with the first exemplary embodiment for compensating the loop delay in digital manner;

FIG. 4A is a schematic functional block diagram of a delta-sigma ADC modulator loop in accordance with a second exemplary embodiment for compensating a loop delay; and

FIG. 4B is a schematic functional block diagram of the delta-sigma ADC modulator loop in accordance with the second exemplary embodiment for compensating the loop delay in analog manner.

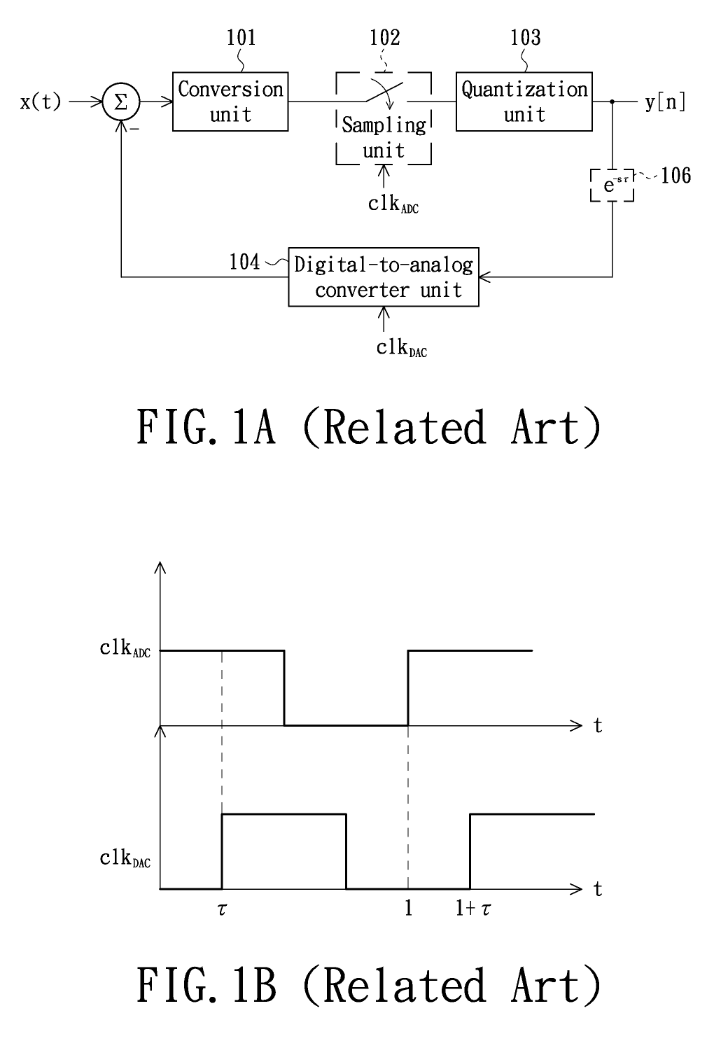

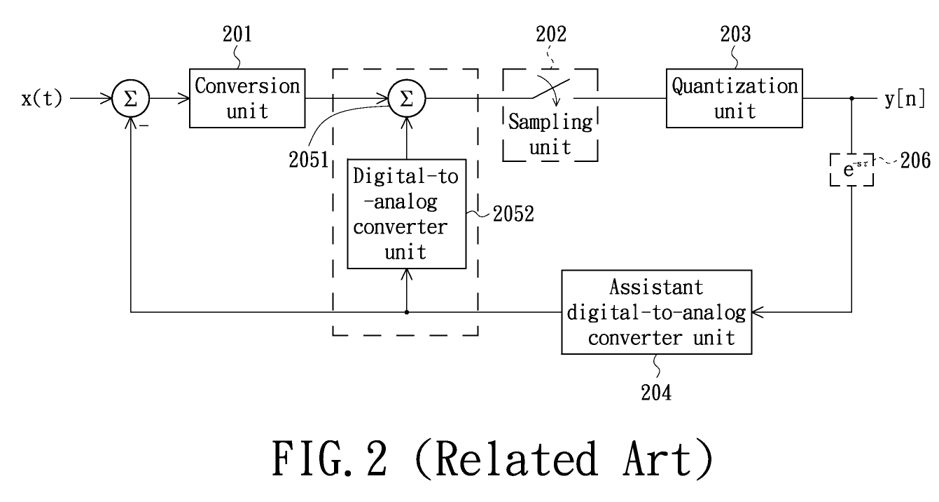

### DETAILED DESCRIPTION

In the following detailed description of the preferred embodiments, reference is made to the accompanying drawings which form a part hereof, and in which are shown by way of illustration specific embodiments in which the disclosure may be practiced. It is to be understood that other embodiment may be utilized and structural changes may be made without departing from the scope of the disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Accordingly, the descriptions will be regarded as illustrative in nature and not as restrictive.

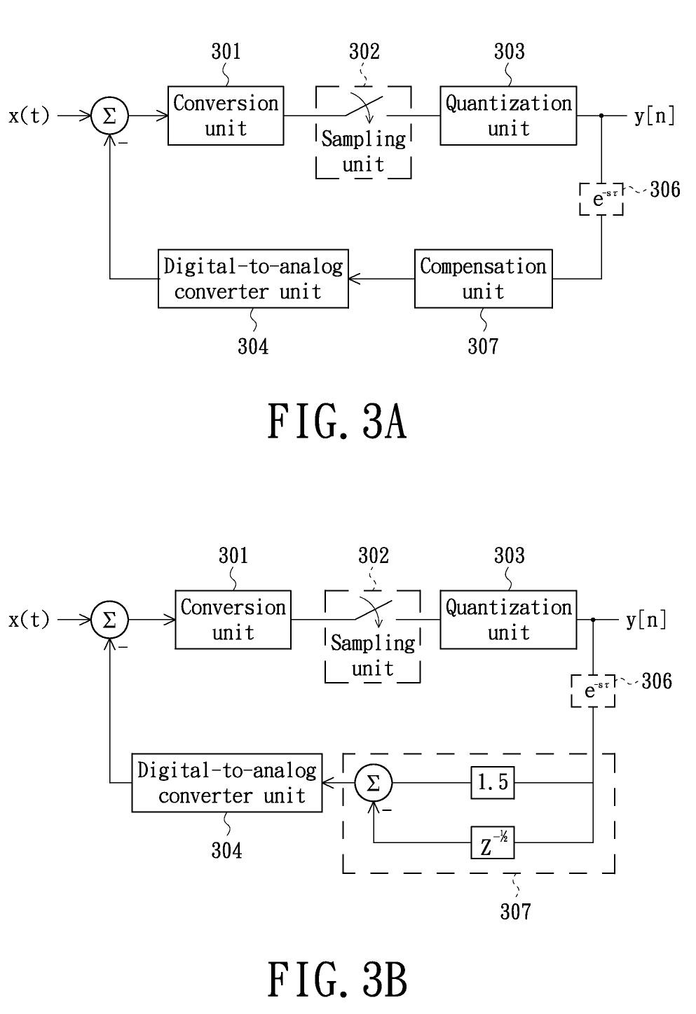

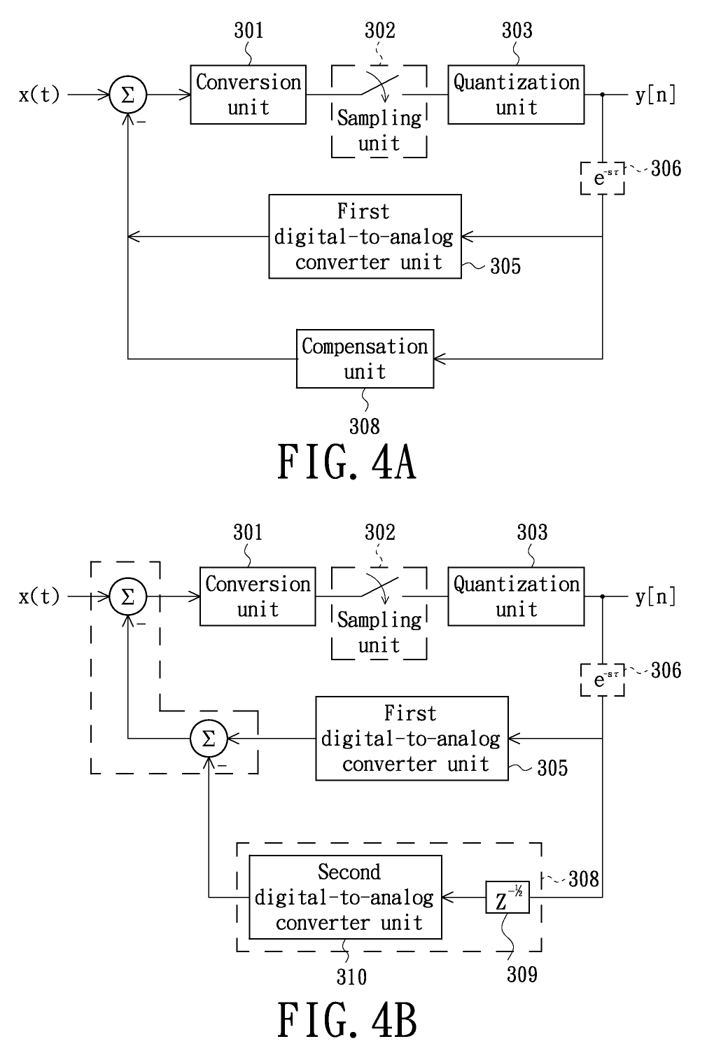

Since the transfer function H(s) of the delta-sigma ADC modulator loop would generate an extra loop delay e−^{sτ} caused by a delay resulting from non-ideal effect, therefore the disclosure proposes a solution of multiplying the transfer function with a factor for compensating the loop delay e−^{sτ}, i.e., using a functional block equivalent to e^{sτ} to counteract the loop delay e−^{sτ} to thereby make the transfer function of the system retrieve back to the original H(s). In the disclosure, descriptions with reference to FIGS. 3A, 3B, 4A and 4B are made to explain how to realize compensation units respectively in digital and analog manners, to thereby provide the functional blocks equivalent to e^{sτ}, so as to improve the loop delay by compensation transfer functions respectively provided by the compensation units and prevent the negative effect to the F.O.M. of the delta-sigma ADC modulator loop of the disclosure.

More specifically, FIG. 3A is a schematic functional block diagram of a delta-sigma ADC modulator loop in accordance with a first exemplary embodiment for compensating the extra loop delay. For the convenience of following description, the delta-sigma ADC modulator loop can be divided into a main path (i.e., generally forward path) in the upper half part and a feedback path in the lower half part. Herein, the signal processing flow direction of the main path is oriented from left to right, that is, an input signal is processed to thereby generate an output signal. On the other hand, the signal processing flow direction of the feedback path is oriented from right to left, that is, the output signal flows through the feedback path to thereby generate a feedback signal for feedback.

The main path includes a conversion unit 301, a sampling unit 302 and a quantization unit 303. In detail, the conversion unit 301 is to provide a transfer function for converting an error signal to generate a converted signal. The sampling unit 302 samples the converted signal to obtain a sampling signal. The quantization unit 303 is for quantizing the sampling signal to obtain the output signal.

The feedback path includes a digital-to-analog converter unit 304 and a compensation unit 307. It is noted that since the loop delay 306 only is a phenomenon in the system rather than a physical circuit, and thus the loop delay 306 in FIG. 3A is depicted by a dashed rectangle. In simple terms, the compensation unit 307 is arranged between the digital-to-analog converter unit 304 and the output signal to improve the influence of the loop delay. Herein, the compensation unit 307 can use a method similar to Taylor expansion formula to obtain a corresponding transfer function and be realized in a digital manner.

The digital-to-analog converter unit 304 converts the compensated output signal from a digital format to an analog format, the output signal of the analog format then is subtracted from the input signal through an adder to obtain the error signal. At last, the subtraction result serves as the input of the conversion unit 301. That is, the error signal is obtained according to the input signal cooperative with the feedback signal.

FIG. 3B is a schematic functional block diagram of the delta-sigma ADC modulator loop in accordance with the first exemplary embodiment for compensating the loop delay in digital manner.

Because the compensation unit 307 needs to aim at the compensation for the time delay and provide the compensation transfer function of e^{sτ}. In a discrete-time domain, s=1−z^{-0.5}, and e^{sτ} can be obtained using an approximation formula. For example, the Taylor expansion formula can be used to obtain an approximation value e^{sτ}=1+sτ. Based on the convenience of application, herein it is assumed that the time delay τ=0.5 period, and therefore e^{sτ}=1+sτ=1.5−z^{-0.5}. It is found that such formula includes a constant operand (1.5) and a sampling time delay operand (z^{-0.5}). Accordingly, after realizing the transfer function in the compensation unit 307, the compensation unit 307 sends a feedback through the digital-to-analog converter unit 304. In other words, the compensation unit 307 can use the transfer function of (1.5−z^{-0.5}) to compensate 0.5 period delay occurred between a clock signal of the digital-to-analog converter unit 304 and a clock pulse of the sampling unit 302.

In the first exemplary embodiment, the output signal of the delta-sigma ADC modulator loop is processed by the constant operand and the sampling time delay operand to respectively obtain a constant operation output signal and a delay operation output signal, and the compensation signal then is obtained by adding the constant operation output signal with the delay operation output signal through an adder. That is, the compensation signal is obtained according to the constant operation output signal outputted from the constant operand and the delay operation output signal outputted from the sampling time delay operand.

It is noted that the compensation transfer function for the compensation unit 307 can be adjusted according to different applications, besides deducing different compensation transfer functions for different time delay values in similar manner, the constant used in the compensation transfer function can also be adjusted according to actual requirements. For example, in consideration of the realization of logic circuit, if the constant in the compensation unit 307 is changed to 2, the circuit of the compensation unit 307 is easier to be designed than the circuit of the compensation unit 307 whose constant is 1.5. Accordingly, the transfer function (1.5−z^{-0.5}) provided by the compensation unit 307 can be changed to be (2−z^{-0.5}).

FIG. 4A is a schematic functional block diagram of a delta-sigma ADC modulator loop in accordance with a second exemplary embodiment for compensating the loop delay. The definitions of the main path and the feedback path are similar to that in the above-mentioned first exemplary embodiment, and thus the description will not be repeated.

Compared with FIG. 4A with FIG. 3A, it can be found that the compensation unit 308 in the feedback path can be realized in analog manner except from being arranged between the first digital-to-analog converter unit 305 and the output signal like the compensation unit 307 of the first exemplary embodiment. When the compensation unit 308 is realized in analog manner, the compensation unit 308 and the first digital-to-analog converter unit 305 for example are arranged between the output signal and the input signal in parallel. That is, the first digital-to-analog converter unit 305 and the compensation unit 308 are both connected in the feedback path between the output signal and the input signal.

FIG. 4B is a schematic functional block diagram of the delta-sigma ADC modulator loop in accordance with the second exemplary embodiment for compensating the loop delay in analog manner. Similar to the digital manner, in FIG. 4B, the compensation unit 308 includes a second digital-to-analog converter unit 310 and a sampling time delay operand 309. The compensation transfer function for the compensation unit 308 is obtained according to the time delay and the approximation formula. Herein, the sampling time delay operand (Z^{-1/2}) 309 uses a 1/2 period delay as an example, but it is not to limit the disclosure.

In FIG. 4B, it is assumed that a first current flowing through the first digital-to-analog converter unit 305 is I1, a second current flowing through the second digital-to-analog converter unit 310 is I2, the first current I1 advantageously is a multiple of the second current I2, for example, I1=1.5×I2.

It is noted that, for individually explaining the transfer function (1.5−z^{-0.5}) provided by the compensation unit 308, FIG. 4B uses an adder icon Σ to express the signal sum between the first digital-to-analog converter unit 305 and the compensation unit 308 to emphasize that the compensation unit 308 and the first digital-to-analog converter unit 305 are arranged in the feedback path in parallel, and use another adder to add the signals of the feedback path and the main path. But in actual applications, the two adders can be combined into a single one.

Compensation delta-sigma ADC modulator systems for common use primarily are 2˜5 orders systems, but a similar method can also be applied to other different orders compensation delta-sigma ADC modulator systems. In addition, the above-mentioned functional blocks can use hardware, software, or the combination of software and hardware to realize, such as using application specific integrated circuit (ASIC) chips or performing a programming to DSP.

The above description is given by way of example, and not limitation. Given the above disclosure, one skilled in the art could devise variations that are within the scope and spirit of the disclosure disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A delta-sigma ADC modulator loop adapted for converting a continuous-time input signal into a discrete-time output signal, the delta-sigma ADC modulator loop comprising:
a conversion unit, for converting an error signal relevant to the input signal through a transfer function to thereby generate a converted signal;
a sampling unit, for sampling the converted signal to thereby generate a sampling signal;
a quantization unit, for quantizing the sampling signal to obtain the output signal;
a compensation unit, for receiving the output signal and compensating a time delay of the received output signal to thereby generate a compensation signal; and
a digital-to-analog converter unit, electrically coupled to the compensation unit and the conversion unit, for converting the compensation signal to thereby generate a feedback signal for regulating the error signal.

2. The delta-sigma ADC modulator loop as claimed in claim 1, wherein a compensation transfer function for the compensation unit is obtained according to the time delay and an approximation formula.

3. The delta-sigma ADC modulator loop as claimed in claim 1, wherein the compensation unit comprises a constant operand and a sampling time delay operand.

4. The delta-sigma ADC modulator loop as claimed in claim 3, wherein the output signal is converted into a constant operation output signal and a delay operation output signal respectively according to the constant operand and the sampling time delay operand, and the compensation signal correspondingly is obtained according to the constant operation output signal and the delay operation output signal.

5. The delta-sigma ADC modulator loop in claim 1, wherein the error signal is obtained according to the input signal cooperative with the feedback signal.

6. A delta-sigma ADC modulator loop adapted for converting a continuous-time input signal into a discrete-time output signal, the delta-sigma ADC modulator loop comprising:
a conversion unit, for converting the input signal through a transfer function to thereby generate a converted signal;
a sampling unit, dynamically connected to the conversion unit, for generating a sampling signal according to the converted signal;
a quantization unit, signally connected to the sampling unit, for quantizing the sampling signal to obtain the output signal;
a first digital-to-analog converter unit, signally connected to the output signal; and
a compensation unit, signally connected to the output signal and the input signal, for providing a delay compensation to the output signal.

7. The delta-sigma ADC modulator loop as claimed in claim 6, wherein a compensation transfer function for the compensation unit to provide the delay compensation is obtained according to a time delay of the output signal and an approximation formula.

8. The delta-sigma ADC modulator loop as claimed in claim 6, wherein the compensation unit and the first digital-to-analog converter unit are arranged between the output signal and the input signal in parallel.

9. The delta-sigma ADC modulator loop as claimed in claim 6, wherein the compensation unit comprises a second digital-to-analog converter unit and a sampling time delay operand.

10. The delta-sigma ADC modulator loop as claimed in claim 9, wherein a first current flowing through the first digital-to-analog converter unit is a multiple of a second current flowing through the second digital-to-analog converter unit.
